(19) United States
(12) Patent Application Publication
(10) Pub. No.: US 2024/0072222 A1
(43) Pub. Date: Feb. 29, 2024

(54) METHOD FOR PRODUCING AN OPTOELECTRONIC COMPONENT, AND OPTOELECTRONIC COMPONENT

(71) Applicant: ams-OSRAM International GmbH, (US)

(72) Inventor: Daniel RICHTER, Bad Abbach (DE)

(21) Appl. No.: 18/021,860

(22) PCT Filed: Aug. 13, 2021
(86) PCT No.: PCT/EP2021/072580

§ 371 Date: Feb. 17, 2023

(30) Foreign Application Priority Data
Aug. 18, 2020 (DE) 10 2020 121 656.4

(51) Int. Cl. H01L 33/62; H01L 25/16

(52) U.S. Cl. CPC H01L 33/62; H01L 25/167; H01L 2933/0066

(57) ABSTRACT

A method for producing an optoelectronic component comprises steps for providing a lead frame, which has a front side and a back side; for forming an inner shaped body, a first portion of the lead frame being embedded in the inner shaped body and a second portion of the lead frame not being embedded in the inner shaped body; for placing an optoelectronic semiconductor chip onto the inner shaped body on the front side of the lead frame; for bending the lead frame such that the first portion of the lead frame is angled with respect to the second portion of the lead frame; and for embedding the lead frame and the inner shaped body in an outer shaped body such that electromagnetic radiation emitted by the optoelectronic semiconductor chip runs through the outer shaped body.

The present invention relates to a method for producing an optoelectronic component, and to an optoelectronic component.

This patent application claims the priority to German patent application DE 10 2020 121 656.4, the disclosure of which is incorporated herein by reference.

The prior art discloses optoelectronic components which emit light in a direction which is parallel to a mounting plane. Such components may comprise internal reflection elements for beam deflection, for example.

An object of the present invention consists in specifying a method for producing an optoelectronic component. A further object of the present invention consists in providing an optoelectronic component. These objects are achieved by a method for producing an optoelectronic component and by an optoelectronic component having the features of the independent claims. Various developments are specified in the dependent claims.

A method for producing an optoelectronic component comprises steps for providing a lead frame having a front side and a rear side, for forming an inner mold body, wherein a first portion of the lead frame is embedded in the inner mold body and a second portion of the lead frame is not embedded in the inner mold body, for arranging an optoelectronic semiconductor chip on the inner mold body on the front side of the lead frame, for bending the lead frame in such a way that the first portion of the lead frame is angled with respect to the second portion of the lead frame, and for embedding the lead frame and the inner mold body in an outer mold body, so that electromagnetic radiation emitted by the optoelectronic conductor chip runs through the outer mold body.

This method enables the production of an optoelectronic component which emits electromagnetic radiation in a direction which is oriented non-perpendicularly to a mounting plane—for example, in a direction which is oriented parallel to the mounting plane. The optoelectronic component obtainable by the method may emit electromagnetic radiation principally in a main emission direction. The directed emission in the case of the optoelectronic component obtainable by this method advantageously takes place without internal light deflection, whereby high efficiency may be achieved.

In an embodiment of the method, after the bending of the lead frame, a further step is carried out for arranging an electronic semiconductor chip on the rear side of the lead frame. In this case, the electronic semiconductor chip, together with the lead frame and the inner mold body, is embedded in the outer mold body. A compact optoelectronic component with a complex functionality is therefore obtainable by this method.

In an embodiment of the method, after the arrangement of the electronic semiconductor chip, a further step is carried out for embedding the electronic semiconductor chip in an embedding material. The electronic semiconductor chip, together with the embedding material, is then embedded in the outer mold body. The embedding material may protect the electronic semiconductor chip from damage caused by external influences. Electrical contacts of the electronic semiconductor chip, for example bonding wires, may be protected from damage by means of the embedding material.

In an embodiment of the invention, the lead frame is bent in such a way that the first portion of the lead frame is angled toward the rear side of the lead frame. The front side of the lead frame may then serve as a contact surface for the electrical contacting of the optoelectronic component obtainable by the method. In the case of the optoelectronic component obtainable by the method, the emission of the electromagnetic radiation advantageously does not take place over the lead frame, which means that shadowing effects may be reliably avoided.

In an embodiment of the method, the lead frame is bent in such a way that the first portion of the lead frame is angled toward the front side of the lead frame. In the case of the optoelectronic component obtainable by this method, the rear side of the lead frame may serve as a contact surface for electrical contacting. The optoelectronic component obtainable by this method may advantageously have particularly compact external dimensions.

In an embodiment of the method, the lead frame is bent in such a way that the first portion of the lead frame is angled at an angle of 90° with respect to the second portion of the lead frame. In the case of the optoelectronic component obtainable by the method, the emission of electromagnetic radiation then advantageously takes place parallel to a mounting plane of the optoelectronic component.

In an embodiment of the method, portions of the lead frame are cut before the bending procedure. Therefore, during the processing steps which precede the bending procedure, the lead frame may still comprise additional, stabilizing connections, which facilitate the processing of the lead frame.

In an embodiment of the method, the inner mold body is formed with a cavity. In this case, the optoelectronic semiconductor chip is arranged in the cavity. The cavity may advantageously serve to form the beam of the electromagnetic radiation emitted by the optoelectronic semiconductor chip.

In an embodiment of the method, after the arrangement of the optoelectronic semiconductor chip, a further step is carried out for arranging a potting material in the cavity. In this case, the optoelectronic semiconductor chip is embedded in the potting material. The potting material may advantageously protect the optoelectronic semiconductor chip from damage caused by external influences. The potting material may also protect the electrical contacts of the optoelectronic semiconductor chip, for example with the bonding wires connected to the optoelectronic semiconductor chip. The potting material may also comprise wavelength-converting particles or scatter particles.

In an embodiment of the method, a multiplicity of inner mold bodies is formed. Portions of the lead frame are embedded in the inner mold bodies in each case. A plurality of inner mold bodies are embedded in the outer mold body together. In this case, the method comprises a further step for dividing the outer mold body to obtain a plurality of parts which each comprise at least one inner mold body. The method therefore advantageously enables parallel production of a multiplicity of similar optoelectronic components. The method can thus be advantageously carried out in a particularly quick and cost-effective manner.

An optoelectronic component comprises a lead frame having a front side and a rear side, an inner mold body, an optoelectronic semiconductor chip arranged on the inner mold body on the front side of the lead frame, and an outer mold body. A first portion of the lead frame is embedded in the inner mold body. A second portion of the lead frame is not embedded in the inner mold body. The lead frame is bent in such a way that the first portion of the lead frame is angled with respect to the second portion of the lead frame. The lead frame and the inner mold body are embedded in the outer mold body. Electromagnetic radiation emitted by the optoelectronic semiconductor chip runs through the outer mold body.

This optoelectronic component has compact external dimensions. As a result of the outer mold body, the optoelectronic component is protected against external influences and can be easily handled. The optoelectronic component is configured to emit electromagnetic radiation in a main emission direction which is oriented other than perpendicularly to a mounting plane of the optoelectronic component. For example, the main emission direction may be oriented parallel to a mounting plane. The emission advantageously takes place without internal deflection within the optoelectronic component, which means that the optoelectronic component may be highly efficient.

In an embodiment of the optoelectronic component, an electronic semiconductor chip is arranged on the rear side of the lead frame. In this case, the electronic semiconductor chip, together with the lead frame and the inner mold body, is embedded in the outer mold body. This optoelectronic component may have a complex functionality as a result of the integrated electronic semiconductor chip. Even so, the optoelectronic component advantageously has very compact external dimensions.

In an embodiment of the optoelectronic component, the electronic semiconductor chip is configured to control the optoelectronic semiconductor chip. The electronic semiconductor chip may be configured, for example, as a driver chip. The optoelectronic component may therefore advantageously have a complex functionality with small external dimensions.

In an embodiment of the optoelectronic component, the lead frame is bent in such a way that the first portion of the lead frame is angled toward the rear side of the lead frame. In this case, the front side of the lead frame may form electrical contact surfaces of the optoelectronic component. In the case of this optoelectronic component, the emission of electromagnetic radiation advantageously does not take place over the lead frame, which means that shadowing effects may be reliably avoided.

In an embodiment of the optoelectronic component, the lead frame is bent in such a way that the first portion of the lead frame is angled toward the front side of the lead frame. In the case of this variant of the optoelectronic component, the rear side of the lead frame may form electrical contact surfaces of the optoelectronic component. This variant of the optoelectronic component may advantageously have particularly compact external dimensions.

In an embodiment of the optoelectronic component, the lead frame is bent in such a way that the first portion of the lead frame is angled at an angle of 90° with respect to the second portion of the lead frame. The emission of electromagnetic radiation in the case of this optoelectronic component advantageously takes place in a direction which is parallel to a mounting plane of the optoelectronic component.

In an embodiment of the optoelectronic component, the inner mold body comprises a cavity. In this case, the optoelectronic semiconductor chip is arranged in the cavity. The cavity of the inner mold body may result in the formation of a beam of electromagnetic radiation emitted by the optoelectronic semiconductor chip.

In an embodiment of the optoelectronic component, a potting material is arranged in the cavity. In this case, the optoelectronic semiconductor chip is embedded in the potting material. The potting material may serve to protect the optoelectronic semiconductor chip from damage caused by external influences. The potting material may also protect bonding wires which are connected to the optoelectronic semiconductor chip. In addition, the potting material may comprise embedded particles, for example scatter particles or wavelength-converting particles.

In an embodiment of the optoelectronic component, in addition to the optoelectronic semiconductor chip, at least one further optoelectronic semiconductor chip is arranged on the inner mold body on the front side of the lead frame. The optoelectronic semiconductor chip and the at least one further optoelectronic semiconductor chip may be configured to emit electromagnetic radiation with different wavelengths. For example, the optoelectronic component may comprise an optoelectronic semiconductor chip for emitting red, green and blue light in each case.

The above-described properties, features and advantages of this invention, and the manner in which they are achieved, will become clearer and more easily understandable in conjunction with the following description of the exemplary embodiments, which are explained in greater detail in association with the drawings, in which, in a schematic illustration in each case:

FIG. 1 shows a plan view of a front side of a lead frame;

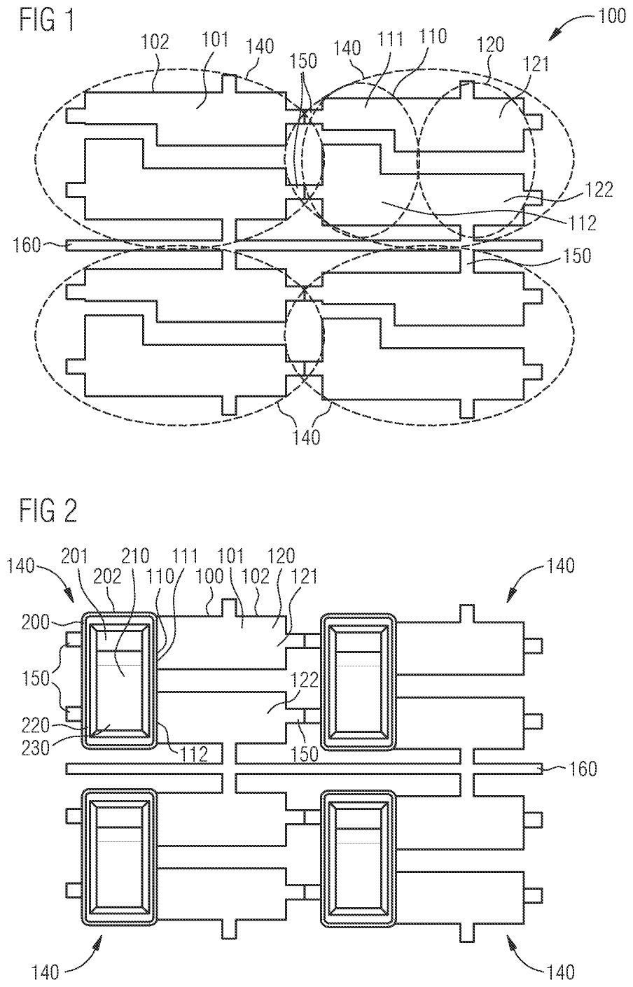

FIG. 2 shows the lead frame with inner mold bodies formed thereon;

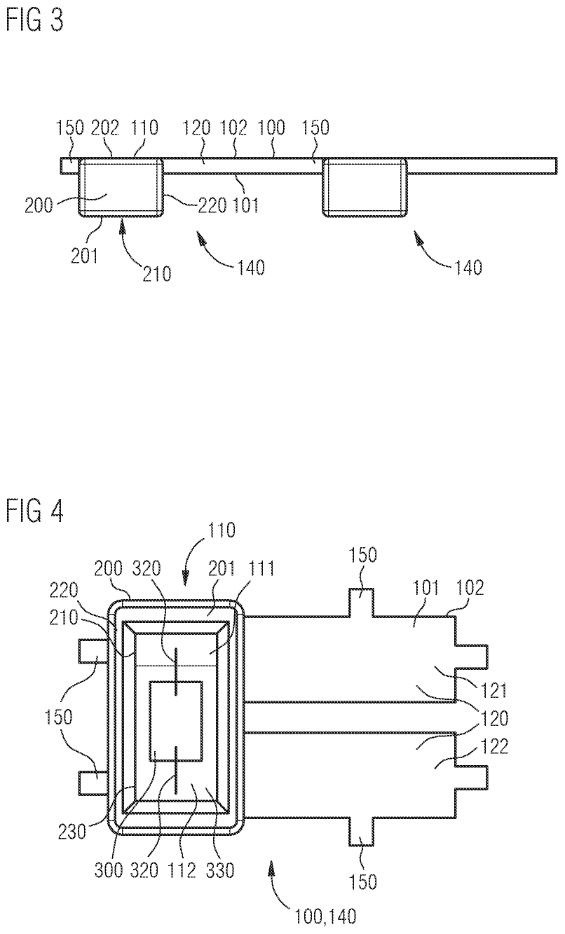

FIG. 3 shows a sectional side view of the lead frame with the inner mold bodies;

FIG. 4 shows a segment of the lead frame with an inner mold body and an optoelectronic semiconductor chip arranged on said inner mold body;

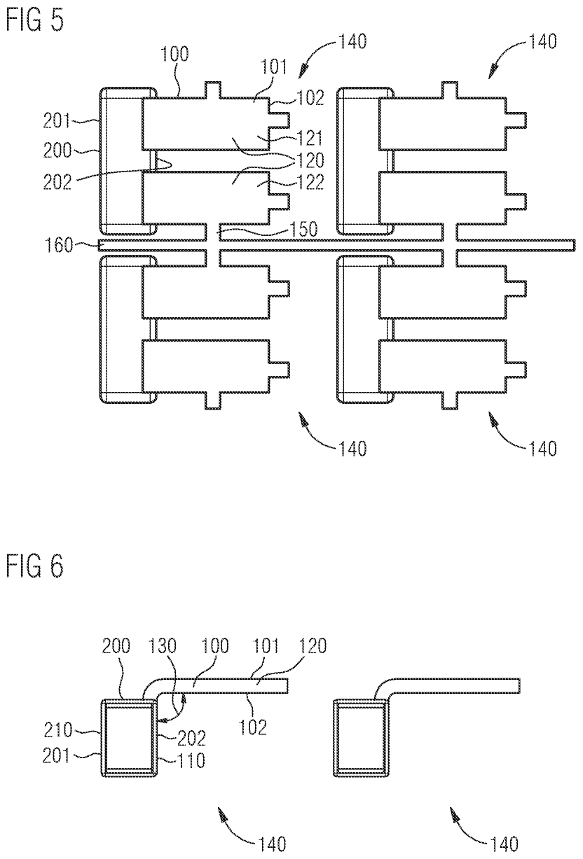

FIG. 5 shows a plan view of the front side of the lead frame after first portions of the lead frame have been angled with respect to second portions of the lead frame;

FIG. 6 shows a sectional side view of the lead frame after the first portions have been angled;

FIG. 7 shows a plan view of the front side of the lead frame after being embedded in an outer mold body;

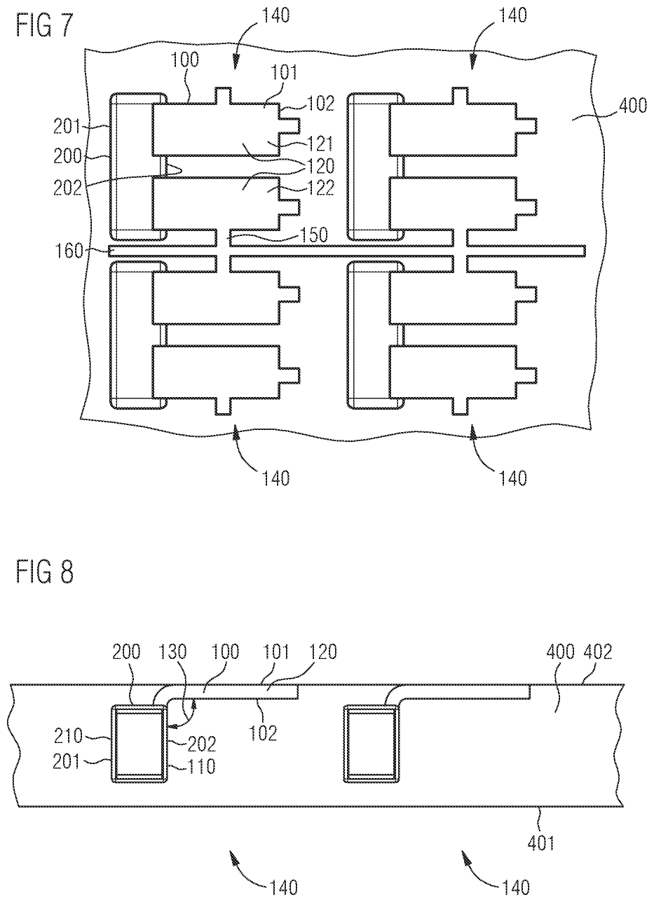

FIG. 8 shows a sectional side view of the lead frame after being embedded in the outer mold body;

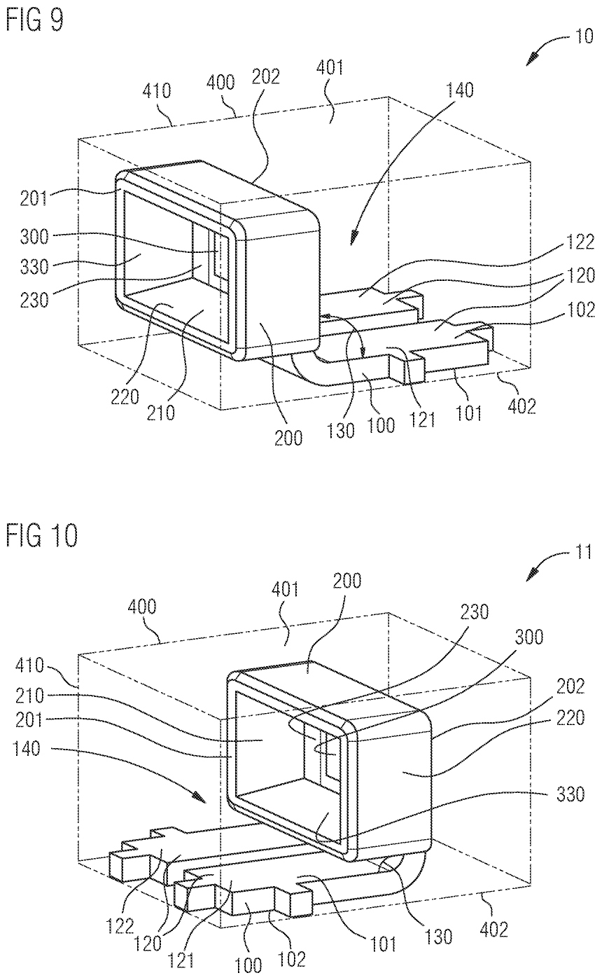

FIG. 9 shows an optoelectronic component obtained by dividing the outer mold body and the lead frame into sections;

FIG. 10 shows a first view of another variant of the optoelectronic component;

FIG. 11 shows a second view of this variant of the optoelectronic component;

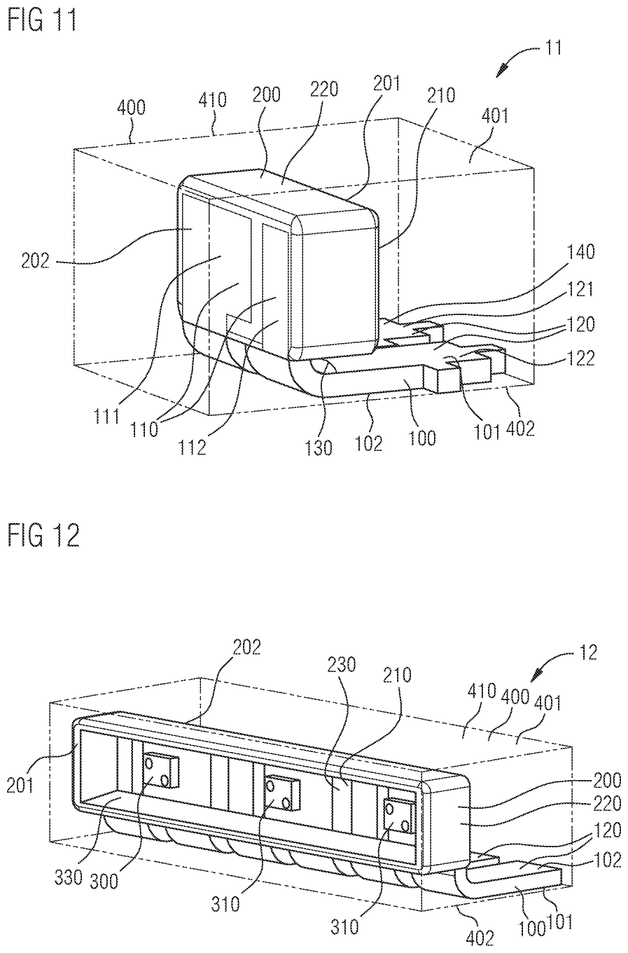

FIG. 12 shows a further variant of the optoelectronic component;

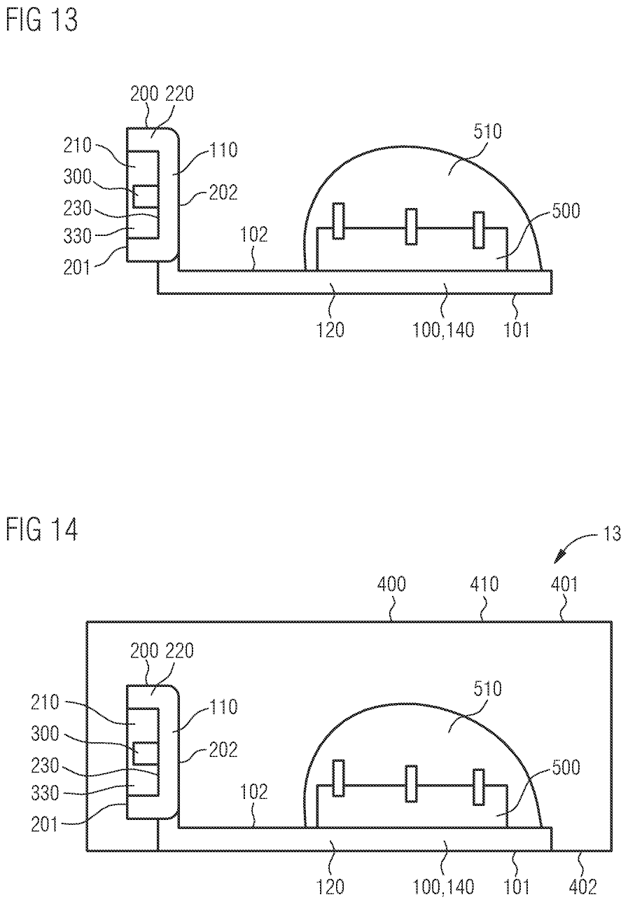

FIG. 13 shows a sectional side view of yet a further variant of the optoelectronic component in an unfinished processing state; and

FIG. 14 shows a sectional side view of this variant of the optoelectronic component.

FIG. 1 shows part of a lead frame 100. The lead frame 100 has a front side 101 (visible in FIG. 1) and a rear side 102, which is opposite the front side 101. The lead frame 100 comprises an electrically conductive material, for example a metal. The lead frame 100 may be manufactured from a thin metal sheet, for example by etching. The lead frame 100 may be configured, for example, as a QFN lead frame, in particular as a QFN panel for example.

In FIG. 1, four similarly configured segments 140 of the lead frame 100 are shown. However, the lead frame 100 may comprise any number of segments 140. The segments 140 are arranged in a regular, two-dimensional arrangement, for example in a rectangular matrix. Stabilizing struts 160, of which one is illustrated by way of example in FIG. 1, may extend between the segments 140 of the lead frame 100. The segments 140 of the lead frame 100 are connected to one another and to the struts 160 via webs 150.

In the example shown in FIG. 1, each segment 140 of the lead frame 100 comprises a first portion 110 and a second portion 120. The first portion 110 in this example is divided into a first sub-portion 111 and a second sub-portion 112 in each case. The second sub-portion 120 is divided into a first sub-portion 121 and a second sub-portion 122 in each case. In each segment 140, the first sub-portion 111 of the first portion 110 is connected cohesively, in one piece, to the first sub-portion 121 of the second portion 120. Accordingly, the second sub-portion 112 of the first portion 110 is connected cohesively, in one piece, to the second sub-portion 122 of the second portion 120. In contrast, the first sub-portion 111 and the second sub-portion 112 of the first portion 110, as well as the first sub-portion 121 and the second sub-portion 122 of the second portion 120, are separate from one another in each segment 140 and are connected merely indirectly to one another via the webs 150, the struts 160 and the further segments 140.

FIG. 2 shows a plan view of the front side 101 of the lead frame 100 in a processing state which follows FIG. 1 time-wise. FIG. 3 shows a sectional side view of the lead frame 100 in the processing state shown in FIG. 2.

A respective inner mold body 200 has been formed on each segment 140 of the lead frame 100. The inner mold bodies 200 are separate and spaced from one another.

The inner mold bodies 200 have been formed by means of a molding process, for example by injection molding. It is expedient to form the inner mold bodies 200 on all segments 140 of the lead frame 100 at the same time in a single processing step. The inner mold bodies 200 have been formed from a plastic material, for example from a thermoplastic or a thermosetting plastic.

The first portions 110 of the segments 140 of the lead frame 100 are each embedded in the inner mold bodies 200 in that the material of the inner mold bodies 200 has been molded around the first portions 110 as the inner mold bodies 200 are formed. The second portions 120 have not been embedded in the inner mold bodies 200 in each case.

Each inner mold body 200 comprises an upper side 201 and an underside 202, which is opposite the upper side 201. In the example shown in FIGS. 2 and 3, the underside 202 of the inner mold body 200 terminates flush with the rear side 102 of the lead frame 100, whilst the upper side 201 of the inner mold body 200 is elevated above the front side 101 of the lead frame 100. However, the underside 202 of the inner mold body 200 might also project beyond the rear side 102 of the lead frame 100, for example. It is likewise possible that the upper side 201 of the inner mold body 200 also terminates flush with the front side 101 of the lead frame 100.

A cavity 210, which comprises a base 230 and a circumferential wall 220, is formed in the upper side 201 of each inner mold body 200. The first sub-portion 111 and the second sub-portion 112 of the first portion 110 of the respective segment 140 of the lead frame 100 are exposed at the base 230 of the cavity 210 of each inner mold body 200. The wall 220, and therefore also the cavity 210, may be omitted. In this case, the upper side 201 of the inner mold body 200 may terminate flush with the front side 101 of the lead frame 100 and forms the base 230 with the first sub-portion 111, which is exposed in the base 230, and the second sub-portion 112, which is exposed in the base 230, of the first portion 110 of the respective segment 140 of the lead frame 100.

FIG. 4 shows a plan view of a segment 140 of the lead frame 100 in a processing state which follows the illustrations of FIGS. 2 and 3 time-wise.

An optoelectronic semiconductor chip 300 has been arranged on the inner mold body 200 of this segment 140 on the front side 101 of the lead frame 100. The optoelectronic semiconductor chip 300 has been arranged in the cavity 210 of the inner mold body 200 at the base 230 of the cavity 210. If the cavity 210 were not present, the optoelectronic semiconductor chip 300 would be arranged in the upper side 201 of the inner mold body 200, which would form the base 230. Corresponding optoelectronic semiconductor chips 300 have been arranged in each case on the inner mold bodies 200 of the further segments 140 of the lead frame 100.

The optoelectronic semiconductor chip 300 is configured to emit electromagnetic radiation, for example visible light. The optoelectronic semiconductor chip 300 may be, for example, a light-emitting diode chip (LED chip). The optoelectronic semiconductor chip 300 has been configured and arranged on the inner mold body 200 so that electromagnetic radiation which is emitted by the optoelectronic semiconductor chip 300 is emitted in a main emission direction, which is oriented perpendicularly to the upper side 201 of the inner mold body 200 and therefore also perpendicularly to the front side 101 of the lead frame 100.

The optoelectronic semiconductor chip 300 which is arranged on the inner mold body 200 has been electrically conductively connected, by means of two bonding wires 320 in the example shown in the figures, to the sub-portions 111, 112 of the first portion 110 of the segment 140 of the lead frame 100 which are exposed at the base 230 of the cavity 210 of the inner mold body 200. However, the electrically conductive connections may also be established in another manner, for example via solder or adhesive connections.

After the arrangement of the optoelectronic semiconductor chip 300 in the cavity 210 of the inner mold body 200, a potting material 330 has been arranged in the cavity 200. The optoelectronic semiconductor chip 300 has been embedded in the potting material 330. The potting material 330 may comprise a silicone, for example. The potting material 330 serves to protect the optoelectronic semiconductor chip 300 and the bonding wires 320 from damage caused by external influences. The potting material 330 may moreover comprise embedded particles, for example scatter particles or wavelength-converting particles. Wavelength-converting particles may be provided for at least partially converting electromagnetic radiation emitted by the optoelectronic semiconductor chip 300 into electromagnetic radiation of a different wavelength. The potting material 330 may be omitted.

FIG. 5 shows a plan view of the front side 101 of the lead frame 100 in a processing state which follows the illustration in FIG. 4 time-wise. FIG. 6 shows a sectional side view of the lead frame 100 in the processing state of FIG. 5.

Starting with the processing state shown in FIG. 4, those webs 150 of the lead frame 100 which connected the first portions 110 of the lead frame 100 to other portions of the lead frame 100 have been cut. The cutting of the webs 150 may take place, for example, by means of a punching process.

The lead frame 100 has subsequently been bent in each segment 140 in such a way that the first portion 110 of the respective segment 140 of the lead frame 100 has been angled with respect to the second portion 120 of the respective segment 140. The first portions 110 of the lead frame 100 and the inner mold bodies 200 formed on the first portions 110 have been bent out of the plane of the lead frame 100. The first portions 110 of the lead frame 100 and the inner mold bodies 200 which are arranged on the first portions 110 have been angled toward the rear side 102 of the lead frame 100.

In the example shown in FIGS. 5 and 6, the first portions 110 of the lead frame 100 have each been bent through 90° so that an angle 130 of 90° is included in each case between the rear side 102 of the first portion 110 and the rear side 102 of the second portion 120 of each segment 140 of the lead frame 100. However, it is also possible to bend the lead frame 100 in such a way that the angle 130 has another value between 0° and 180°.

FIG. 7 shows the lead frame 100 and the inner mold body 200 in a plan view in a processing state which follows the illustration of FIGS. 5 and 6 time-wise. FIG. 8 shows a sectional side view of the lead frame 100 in the processing state shown in FIG. 7.

The lead frame 100 and the inner mold bodies 200 have been embedded in a common outer mold body 400. The outer mold body 400 may have been formed, for example, by means of a molding process, in particular by compression molding for example. The material of the outer mold body 400 has been molded around the lead frame 100 and the inner mold bodies 200 during the molding process. If a potting material 330 is arranged in the cavities 210 of the inner mold bodies 200, the potting material 330 has also been covered by the material of the outer mold body 400. Otherwise, the material of the outer mold body 400 also extends into the cavities 210 of the inner mold bodies 200 so that the optoelectronic semiconductor chips 300 have been embedded in the material of the outer mold body 400. If cavities 210 are not present, the optoelectronic semiconductor chips 300 have likewise been embedded in the material of the outer mold body 400.

The outer mold body 400 may comprise, for example, a plastic material, for example a silicone or an epoxy. The material of the outer mold body 400 is substantially transparent to electromagnetic radiation emitted by the electromagnetic semiconductor chips 300. If the potting material 330 arranged in the cavities 210 of the inner mold bodies 200 comprise a wavelength-converting material, the material of the outer mold body 400 has a high transparency to electromagnetic radiation generated by the converter material.

The outer mold body 400 comprises an upper side 401 and an underside 402, which is opposite the upper side 401. The outer mold body 400 has been configured such that the front side 101 of the second portions 120 of the segments 140 of the lead frame 100 terminate flush with the underside 402 of the outer mold body 400 and are accessible at the underside 402 of the outer mold body 400. It may be necessary to turn the lead frame 100 before forming the outer mold body 400. After forming the outer mold body 400, it may also be necessary to remove any material of the outer mold body 400 (flash) which has formed an undesirable covering on the front side 101 of the second portions 120 of the segments 140 of the lead frame 100 (deflashing).

FIG. 9 shows a perspective illustration of an optoelectronic component 10, which has been formed by dividing the outer mold body 400 shown in FIGS. 7 and 8 into sections.

Starting with the processing state shown in FIGS. 7 and 8, the outer mold body 400, together with the lead frame 100 embedded in the outer mold body 400, has been divided into sections. By dividing the outer mold body, together with the lead frame embedded in the outer mold body, into sections, a plurality of parts 410 are formed, which each comprise a segment 140 of the lead frame 100 and an inner mold body 200 which is arranged on this segment 140. Each such part 410 forms an optoelectronic component 10. The division of the outer mold body 400 and the lead frame 100 into sections may have taken place, for example, by means of a sawing process.

The underside 402 of the part 410 forming the optoelectronic component 10 forms a mounting side of the optoelectronic component 10. The front side 101 of the second portion 120 of the segment 140 of the lead frame 100 which is exposed at the underside 402 of the part 410 forms electrical contact surfaces of the optoelectronic component 10. The optoelectronic component 10 may therefore be suitable as an SMD component for surface mounting, for example for mounting by means of reflow soldering.

The main emission direction of the optoelectronic semiconductor chip 300 of the optoelectronic component 10 is angled at an angle 130, i.e. through 90° in the example shown, with respect to a direction which is oriented perpendicularly to the mounting plane of the optoelectronic component 10. The electronic component 10 therefore emits electromagnetic radiation in a direction which is parallel to the mounting plane of the optoelectronic component 10. The optoelectronic component 10 may therefore be suitable for coupling electromagnetic radiation into an optical waveguide, for example. The cavity 210 of the inner mold body 200 of the optoelectronic component 10 may result in a bundling of the electromagnetic radiation emitted by the optoelectronic semiconductor chip 300.

Electromagnetic radiation emitted by the optoelectronic semiconductor chip 300 of the optoelectronic component 10 runs through the potting material 330, if this is present, and through the material of the outer mold body 400.

FIGS. 10 and 11 show perspective illustrations of an optoelectronic component 11 from different viewing directions. The optoelectronic component 11 shown in FIGS. 10 and 11 corresponds largely to the optoelectronic component 10 shown in FIG. 9. The method used to produce the optoelectronic component 11 corresponds significantly to the above-described method for producing the optoelectronic component 10. The following merely describes the way in which the optoelectronic component 11 and the method serving to produce the optoelectronic component 11 differ from the optoelectronic component 10 and the method for producing the optoelectronic component 10. Otherwise, the above description of the optoelectronic component 10 and the associated production method also apply to the optoelectronic component 11.

In the case of the optoelectronic component 11, the lead frame 100 is bent in such a way that the first portion 110 of the segment 140 of the lead frame 100 is angled toward the front side 101 of the lead frame. The front side 101 of the first portion 110 and the front side 101 of the second portion 120 of the segment 140 of the lead frame 100 therefore include the angle 130, which lies between 0 and 180° and which, in the example shown in FIGS. 10 and 11, is 90°.

During the production of the optoelectronic component 11, the lead frame 100 and the inner mold bodies 200 are embedded in the outer mold body 400 in such a way that the rear side 102 of the second portions 120 of the lead frame 100 terminates flush with the underside 402 of the outer mold body 400. It may be possible to dispense with previously turning the conductor frame 100 here. In the case of the optoelectronic component 11, the rear side 102 of the sub-portions 121, 122 of the second portion 120 of the segment 140 of the lead frame 100 therefore forms the electrical contact surfaces of the optoelectronic component 11.

In the case of the optoelectronic component 11, the emission of electromagnetic radiation by the optoelectronic semiconductor chip 300 from the cavity 210 of the inner mold body 200 takes place over the front side 101 of the second portion 120 of the lead frame 100.

FIG. 12 shows a schematic perspective illustration of an optoelectronic component 12 according to a further variant. The optoelectronic component 12 of FIG. 12 corresponds largely to the optoelectronic component 10 shown in FIG. 9 and may be produced by means of a very similar method. The following merely describes the way in which the optoelectronic component 12 and the method used to produce the optoelectronic component 12 differ from the optoelectronic component 10 and the associated production method. In other respects, the description of the optoelectronic component 10 and the associated production method also apply to the optoelectronic component 12 of FIG. 12.

To produce the optoelectronic component 12, a lead frame 100 is used, in which the first portion 110 and the second portion 120 of each segment 140 each comprise more than two sub-portions. More than one optoelectronic semiconductor chip 300 may therefore be arranged and electrically contacted in the cavity 210 of the inner mold body 200. In the example shown in FIG. 12, in addition to the optoelectronic semiconductor chip 300, two further optoelectronic semiconductor chips 310 have been arranged in the cavity 210 of the inner mold body 200 on the front side 101 of the lead frame 100. The further optoelectronic semiconductor chips 310 may be configured, for example, to emit electromagnetic radiation with wavelengths which differ from those of the optoelectronic semiconductor chip 300. For example, the optoelectronic semiconductor chip 300 and the further optoelectronic semiconductor chips 310 may be configured to emit light with wavelengths in the red, green and blue spectral ranges. It goes without saying that the optoelectronic component 12 might also comprise only one further optoelectronic semiconductor chip 310 or more than two further optoelectronic semiconductor chips 310.

It is likewise possible to bend the lead frame 100 for the optoelectronic component 12 in the same way as for the optoelectronic component 11 of FIGS. 10 and 11.

FIG. 13 shows a schematic sectional side view of a segment 140 of the lead frame 100 during the implementation of a further variant of the production method described above.

In the case of this variant of the production method, after the bending of the lead frame 100, in a further production step, an electronic semiconductor chip 500 has been arranged on the rear side 102 of the lead frame 100 on the second portion 120 of the segment 140 (shown in FIG. 13) of the lead frame 100. The electronic semiconductor chip 500 has then been electrically conductively connected to the sub-portions 121, 122 of the second portion 120 of the lead frame 100, for example via bonding wires. Corresponding electronic semiconductor chips 500 have also been arranged and electrically contacted on the further segments 140 of the lead frame 100.

The electronic semiconductor chip 500 may be configured, for example, to control the optoelectronic semiconductor chip 300 of the respective segment 140 of the lead frame 100. If further optoelectronic semiconductor chips 310 are present in addition to the optoelectronic semiconductor chip 300, the electronic semiconductor chip 500 may be configured to control the optoelectronic semiconductor chip 300 and all further optoelectronic semiconductor chips 310. To this end, the electronic semiconductor chip 500 may be configured, for example, as a driver chip. However, the electronic semiconductor chip 500 may also have other or further functionalities.

After the arrangement of the electronic semiconductor chip 500, the electronic semiconductor chip 500 has been embedded in an embedding material 510. The embedding material 510 may serve to protect the electronic semiconductor chip 500 and the bonding wires which are connected to the electronic semiconductor chip 500. The embedding material 510 may be, for example, a plastic material, for example a silicone or an epoxy. However, the embedding of the electronic semiconductor chip 500 in the embedding material 510 may also be omitted.

FIG. 14 shows a schematic sectional side view of an optoelectronic component 13, which has been produced by further processing of the segment 140 (shown in FIG. 13) of the lead frame 100.

Starting with the processing state shown in FIG. 13, the lead frame 100 has been embedded in the outer mold body 400, as described above with reference to the production of the optoelectronic component 10. The outer mold body 400 has been formed such that the underside 402 of the outer mold body 400 terminates flush with the front side 101 of the second portions 120 of the lead frame 100. The electronic semiconductor chip 500 and the embedding material 510 which surrounds the electronic semiconductor chip 500 have been embedded in the outer mold body 400, together with the lead frame 100 and the inner mold body 200.

The outer mold body 400 and the lead frame 100 which is embedded in the outer mold body 400 have subsequently been divided into sections in the manner already described in order to form the optoelectronic component 13.

The invention has been illustrated and described in greater detail with reference to the preferred exemplary embodiments. However, the invention is not restricted to the disclosed examples. Instead, other variations may be derived therefrom by a person skilled in the art without departing from the scope of the invention.

### LIST OF REFERENCE SIGNS

10 Optoelectronic component
11 Optoelectronic component
12 Optoelectronic component
13 Optoelectronic component
100 Lead frame
101 Front side
102 Rear side
110 First portion
111 First sub-portion
112 Second sub-portion
120 Second portion
121 First sub-portion
122 Second sub-portion
130 Angle
140 Segment
150 Web
160 Strut
200 Inner mold body
201 Upper side
202 Underside
210 Cavity
220 Wall
230 Base
300 Optoelectronic semiconductor chip
310 Further optoelectronic semiconductor chip
320 Bonding wire
330 Potting material
400 Outer mold body
401 Upper side
402 Underside
410 Part
500 Electronic semiconductor chip
510 Embedding material

1. A method for producing an optoelectronic component, having the following steps:
providing a lead frame having a front side and a rear side;
forming an inner mold body, wherein a first portion of the lead frame is embedded in the inner mold body and a second portion of the lead frame is not embedded in the inner mold body;
arranging an optoelectronic semiconductor chip on the inner mold body on the front side of the lead frame;
bending the lead frame in such a way that the first portion of the lead frame is angled with respect to the second portion of the lead frame;
embedding the lead frame and the inner mold body in an outer mold body, so that electromagnetic radiation emitted by the optoelectronic semiconductor chip runs through the outer mold body.

2. The method as claimed in claim 1,
wherein, after the bending of the lead frame, the following further step is carried out:
arranging an electronic semiconductor chip on the rear side of the lead frame,
wherein the electronic semiconductor chip, together with the lead frame and the inner mold body, is embedded in the outer mold body.

3. The method as claimed in claim 2,
wherein, after the arrangement of the electronic semiconductor chip, the following further step is carried out:
embedding the electronic semiconductor chip in an embedding material, wherein the electronic semiconductor chip, together with the embedding material, is embedded in the outer mold body.

4. The method as claimed in claim 1, wherein the lead frame is bent in such a way that the first portion of the lead frame is angled toward the rear side of the lead frame.

5. The method as claimed in claim 1, wherein the lead frame is bent in such a way that the first portion of the lead frame is angled toward the front side of the lead frame.

6. The method as claimed in claim 1, one of the preceding claims, wherein the lead frame is bent in such a way that the first portion of the lead frame is angled at an angle of 90° with respect to the second portion of the lead frame.

7. The method as claimed in claim 1, wherein portions of the lead frame are cut before the bending procedure.

8. The method as claimed in claim 1,
wherein the inner mold body is formed with a cavity,
wherein the optoelectronic semiconductor chip is arranged in the cavity.

9. The method as claimed in claim 8,
wherein, after the arrangement of the optoelectronic semiconductor chip, the following further step is carried out:
arranging a potting material in the cavity, wherein the optoelectronic semiconductor chip is embedded in the potting material.

10. The method as claimed in claim 1,
wherein a multiplicity of inner mold bodies is formed, wherein portions of the lead frame are embedded in the inner mold body in each case,
wherein a plurality of inner mold bodies are embedded in the outer mold body together, wherein the method comprises the following further step:
dividing the outer mold body to obtain a plurality of parts which each comprise at least one inner mold body.

11. An optoelectronic component having a lead frame having a front side and a rear side,
an inner mold body,
an optoelectronic semiconductor chip arranged in the inner mold body on the front side of the lead frame,
and an outer mold body,
wherein a first portion of the lead frame is embedded in the inner mold body and a second portion of the lead frame is not embedded in the inner mold body,
wherein the lead frame is bent in such a way that the first portion of the lead frame is angled with respect to the second portion of the lead frame,
wherein the lead frame and the inner mold body are embedded in the outer mold body,
wherein electromagnetic radiation emitted by the optoelectronic semiconductor chip runs through the outer mold body.

12. The optoelectronic component as claimed in claim 11,
wherein an electronic semiconductor chip is arranged on the rear side of the lead frame,
wherein the electronic semiconductor chip, together with the lead frame and the inner mold body, is embedded in the outer mold body.

13. The optoelectronic component as claimed in claim 12,
wherein the electronic semiconductor chip is configured to control the optoelectronic semiconductor chip.

14. The optoelectronic component as claimed in claim 11,
wherein the lead frame is bent in such a way that the first portion of the lead frame is angled toward the rear side of the lead frame.

15. The optoelectronic component as claimed in claim 11,
wherein the lead frame is bent in such a way that the first portion of the lead frame is angled toward the front side of the lead frame.

16. The optoelectronic component as claimed in claim 11, one of the preceding claims,
wherein the lead frame is bent in such a way that the first portion of the lead frame is angled at an angle of 90° with respect to the second portion of the lead frame.

17. The optoelectronic component as claimed in claim 11,
wherein the inner mold body comprises a cavity,
wherein the optoelectronic semiconductor chip is arranged in the cavity.

18. The optoelectronic component as claimed in claim 17,
wherein a potting material is arranged in the cavity, wherein the optoelectronic semiconductor chip is embedded in the potting material.

19. The optoelectronic component as claimed in claim 11,
wherein, in addition to the optoelectronic semiconductor chip, at least one further optoelectronic semiconductor chip is arranged on the inner mold body on the front side of the lead frame.
